(19) United States
(12) Patent Application Publication
(10) Pub. No.: US 2009/0271978 A1
(43) Pub. Date: Nov. 5, 2009

(54) Foil Perforating Needle For Detaching A Small Die From The Foil

(75) Inventor: René Josef Ulrich, Weggis (CH)

Correspondence Address: Nixon Peabody LLP, 200 Page Mill Road, Palo Alto, CA, 94306, US

(73) Assignee: Oerlikon Assembly Equipment AG, Steinhausen, Cham (CH)

(21) Appl. No.: 12/263,034

(22) Filed: Oct. 31, 2008

Related U.S. Application Data
(60) Provisional application No. 61/002,700, filed on Nov. 8, 2007.

(30) Foreign Application Priority Data
Oct. 31, 2007 (CH) 1702/07

(51) Int. Cl. H05K 3/04

(52) U.S. Cl. 29/829

(57) ABSTRACT

A foil perforation needle for perforating a foil and detaching a die from the foil has a shaft, which passes at one end into a blade having a cutting edge. The cutting edge minimizes the strain per unit area occurring upon impact on the foil and, after the perforation of the foil, upon impact on the die.

### PRIORITY CLAIM

Applicant hereby claims foreign priority under 35 U.S.C § 119 from Swiss patent application no. 1702/07 filed Oct. 31, 2007 and from U.S. provisional patent application No. 61/002,700 filed Nov. 8, 2007, the disclosures of which are herein incorporated by reference.

### FIELD OF THE INVENTION

The invention concerns a foil perforating needle for detaching a die, in particular a small die, from a foil. Small semiconductor chips are called “small dies” in the professional jargon. “Small dies” are understood in the context of the present invention as semiconductor chips whose lateral length is in the range from only 0.1 mm to approximately 1.2 mm.

### BACKGROUND OF THE INVENTION

In the mounting of dies, the dies sawn out of a wafer and adhering to a foil are provided on a wafer table. The mounting is performed using mounting machines, which are known to those skilled in the art as die bonders. A die bonder contains a pick and place system, which comprises a bond head having a chip gripper. The pick and place system moves the bond head back and forth between the wafer table and the substrate, the chip gripper accommodating the die provided by the wafer table and placing it on the substrate. The chip gripper contains a suction element having a suction opening, so that it may hold the die using vacuum. The suction force is proportional to the area of the suction opening and is accordingly low for small dies. In many cases, the suction force is not sufficiently strong to detach the die adhering to the foil from the foil. The removal of the provided die from the foil is therefore supported by a die ejector situated below the foil, in that at least one needle housed in the die ejector perforates the foil from the bottom side and then lifts the die adhering on the top side of the foil off of the foil, so that the suction force of the chip gripper is then sufficient to accept and hold the die. For small dies, only a single needle may be used for reasons of space. Such a needle contains a round tip which has an opening angle of approximately 10° and a radius of only approximately 18 μm. Such needles are known from innumerable patent specifications.

A needle is known from US 2005-006029, which is used for detaching a die from a foil, whose tip is formed as a wedge having a flat section, the flat section being wide enough that it does not act as a cutting edge and the needle thus does not perforate the foil.

Because the highest possible throughput of the mounting machines is required, the detachment of the die from the foil must occur in a very short time. Various undesired effects occur:
Dies whose rear side is damaged upon impact of the needle occur again and again.
The tip of the needle is damaged without this being noticed, which then in turn results in damage of the dies.

### SUMMARY OF THE INVENTION

The invention is based on the object of determining and eliminating the reasons for the cited effects.

The invention is based on the finding that upon impact of the needle on the foil and, after the perforation of the foil, upon impact on the die, significant forces are exerted on the needle and also on the die. These forces result in the damages cited in the introduction. The needle is a tiny rounded tip: the surface of the needle which contacts the die is an approximately punctate surface, which is subject to a very high strain upon impact. The strain per unit area occurring is greater on the side of the needle than the material properties permit, which usually results in deformations and damage of the needle tip in a short time. The occurring strain per unit area is also too great on the side of the die, however. It is therefore suggested by the present invention that the needle still be used as a foil perforation needle, but not be implemented having a tip, but rather as a blade having a cutting edge to significantly reduce the strain per unit area. A foil perforation needle for detaching a die from the foil is therefore according to the invention formed as a blade with a cutting edge. The length of the cutting edge is advantageously at least 10 times as long as its width. It is also possible to provide the foil perforation needle with multiple blades, their cutting edges lying in a same plane. This plane preferably runs approximately perpendicular to a longitudinal direction of the shaft. The number of the blades and their relative orientation to one another are not subject to any limits.

For the optimum detachment of the die from the foil, it is advantageous if the length of the cutting edge of the foil perforation needle is in the range between 25% and 50% of the length of the shorter side of the die. It is especially advantageous if the length of the cutting edge is approximately ⅓ of the length of the shorter side of the die. Furthermore, it is advantageous if the cutting edge is not oriented parallel to that or those crystal axes of the die which are most endangered by fracture. In silicon, for example, these are the [100] and [010] crystal axes.

### BRIEF DESCRIPTION OF THE DRAWING FIGURES

The accompanying drawings, which are incorporated into and constitute a part of this specification, illustrate one or more embodiments of the present invention and, together with the detailed description, serve to explain the principles and implementations of the invention. The figures are not to scale. In the drawings:

FIG. 1 shows a foil perforation needle according to the invention in a top view of the needle tip,

FIGS. 2, 3 show the foil perforation needle in two sections,

FIGS. 4, 5 illustrate the detachment of a die from a foil,

FIG. 6 illustrates a preferred orientation of the foil perforation needle in relation to a die to be detached, and

FIGS. 7-11 show further foil perforation needles according to the invention.

### DETAILED DESCRIPTION OF THE INVENTION

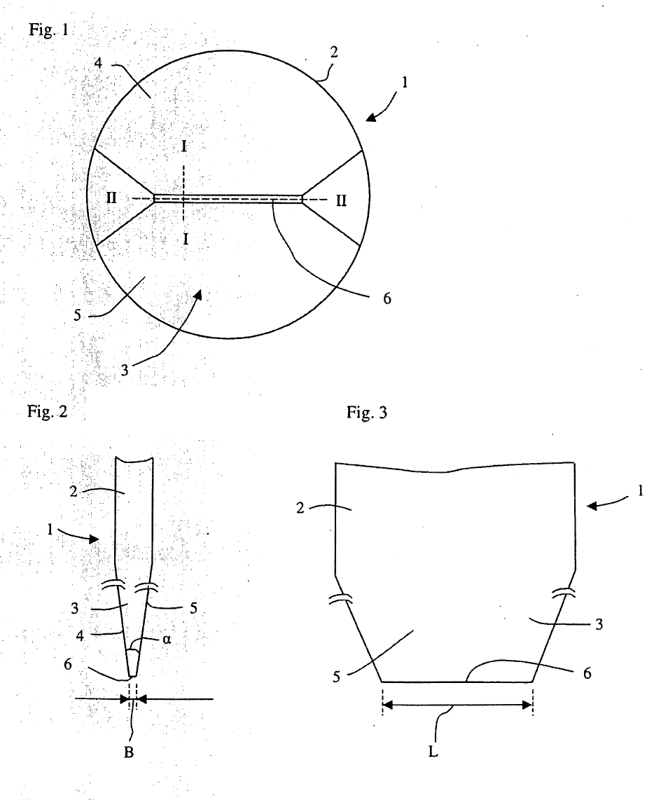

FIG. 1 shows a foil perforation needle 1 according to the invention in a top view of the needle tip. FIGS. 2 and 3 show the foil perforation needle 1 in two sections, which are perpendicular to one another: FIG. 2 shows the foil perforation needle 1 in section along line I-I, FIG. 3 shows the foil perforation needle 1 in section along line II-II of FIG. 1. The foil perforation needle 1 comprises an elongate, typically round shaft 2, which passes at one end into a tip formed as a blade 3. The blade 3 has two lateral faces 4 and 5, which run together at an acute angle α and meet in the cutting edge, which is an elongate, extremely narrow cutting edge 6. The cutting edge 6 has a width B and a length L. The width B is typically approximately 2 μm in the foil perforation needle 1 according to the invention. The length L is preferably adapted to the size of the die to be detached. A die often has a rectangular shape and thus one shorter side and one longer side. The length L of the cutting edge 6 is preferably in the range between 25% and 50% of the length of the shorter side of the die, advantageously it is approximately ⅓ of the length of the shorter side of the die. For a die having a side length of 0.1 mm, an especially advantageous length of approximately L=33 μm thus results. The length L is thus at least 10 times as long as the width B: L≧10*B in any case. The foil perforation needle 1 preferably consists of hard metal, for example, tungsten carbide. The blade 3 may be produced by grinding a typical needle, for example.

In FIG. 2, the cutting edge 6 is shown as a flat edge. The width B of the cutting edge 6 is only a few micrometers, typically approximately 2 μm. The width B of the cutting edge 6 is typically approximately 2 μm and is thus extremely small. The shape of the cutting edge 6 is strongly dependent on the type of the production of the blade 3. The cutting edge 6 may also be rounded or shaped in another way, but the flat shape shown is preferred.

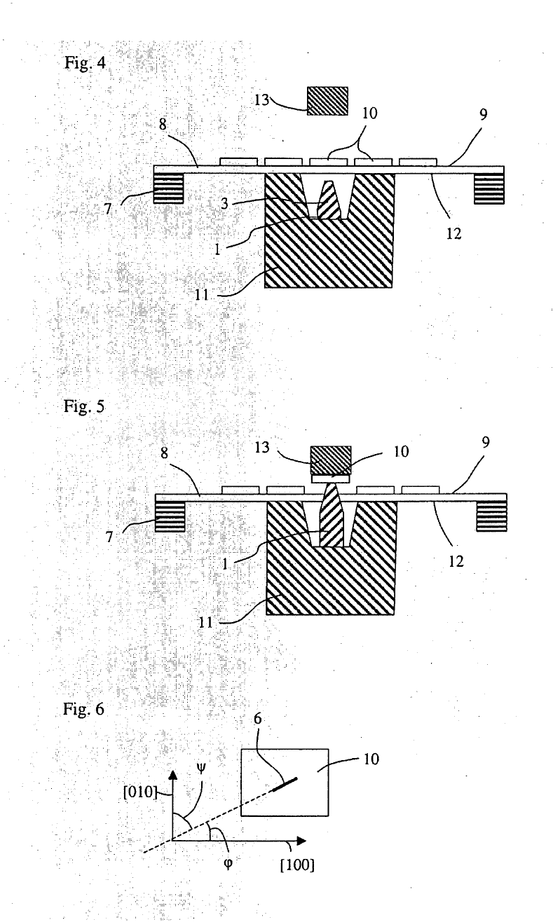

FIG. 4 shows a foil 8 clamped in a frame 7 in section, on whose top side 9 dies 10 situated in rows and columns adhere. A die ejector 11 having a foil perforation needle 1 according to the invention is located on the bottom side 12 of the foil 8. To detach the die 10 from the foil 8, the foil perforation needle 1 is raised, whereby the blade 3 of the foil perforation needle 1 first perforates the foil 8 and then lifts the die 10 off of the foil 8, so that a chip gripper 13 may receive the die 10 and mount it on a substrate. This state is shown in FIG. 5. Such a detachment process is described in detail, for example, in US 20040105750.

Using such a foil perforation needle 1, dies 10 having a side length of only 0.2 mm may be detached from the foil 8 without problems. It has been shown that the width B of the cutting edge 6 slowly increases with time: the foil perforation needle 1 slowly becomes blunt and must therefore be replaced after a certain number of detached dies. This wear is less the longer the length L of the cutting edge 6, because the area under strain during the detachment procedure increases with increasing length L and therefore the strain per unit area decreases with increasing length L. For this reason, it is advantageous to make the length L as large as possible at least for the smallest of the small dies.

FIG. 6 shows a top view of the die 10 provided on a wafer table for removal for the case in which the die 10 is made of silicon, and the [100] and [010] crystal axes of the die 10 run parallel to its lateral edges, and the cutting edge 6 of the blade 3 of the foil perforation needle 1. The [100] and [010] crystal axes are typically the crystal axes most endangered by fracture in dies made of silicon. The blade 3 is preferably oriented in relation to the sides of the die 10 in such a way that the cutting edge 6 does not run parallel to the [100] crystal axis or parallel to the [010] crystal axis, but rather encloses a minimal angle φ with the crystal axis [100] and also a minimal angle ψ with the crystal axis [010]. The angle φ is advantageously greater than 30°, preferably 45°, although in many cases a smaller angle φ of a few degrees also suffices. This is also true for reasons of symmetry for the angle ψ.

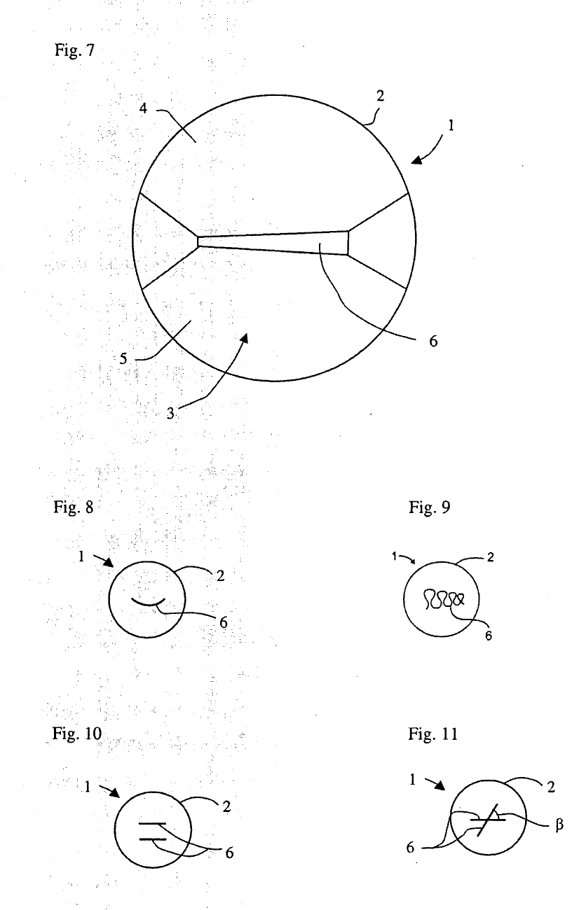

FIG. 7 shows a top view of a foil perforation needle 1 having a single blade 3, in which the cutting edge 6 is not rectangular, but rather trapezoidal. FIGS. 8 and 9 show a top view of a foil perforation needle 1 having a blade 3 whose cutting edge 6 is curved. In FIG. 9 the curvature forms a serpentine. FIGS. 10 and 11 show top views of examples of foil perforation needles 1 according to the invention having more than one blade 3. Only the shaft 2 and the cutting edges 6 of the blades 3 are shown. The cutting edges 6 of the blades 3 are all in the same plane, which preferably runs perpendicular to the longitudinal direction of the shaft. The foil perforation needle 1 shown in FIG. 9 has two blades 3 having cutting edges 6 running parallel to one another. The foil perforation needle 1 shown in FIG. 10 has two blades 3 whose cutting edges 6 are oriented at a predetermined angle β to one another. The angle β is arbitrary and may also be 90°. The length of the cutting edges 6 is also advantageously approximately 10 times greater than their width here.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims and their equivalents.

What is claimed is:

1. A foil perforation needle for detaching a die from the foil, wherein the foil perforation needle is formed as a blade with a cutting edge.

2. The foil perforation needle according to claim 1, wherein the foil perforation needle is formed with at least two blades, each having a cutting edge, and wherein the cutting edges of the blades lie in the same plane.

3. The foil perforation needle according to claim 2, wherein the foil perforation needle has a shaft and wherein said plane runs approximately perpendicular to a longitudinal direction of the shaft.

4. The foil perforation needle according to claim 1, wherein a length of the cutting edge is at least 10 times greater than a width of the cutting edge.

5. The foil perforation needle according to claim 2, wherein a length of the cutting edge is at least 10 times greater than a width of the cutting edge.

6. The foil perforation needle according to claim 3, wherein a length of the cutting edge is at least 10 times greater than a width of the cutting edge.

7. A method for perforating a foil and detaching a die from the foil using a foil perforation needle formed as a blade with a cutting edge, wherein a length of the cutting edge is in the range between 25% and 50% of a length of a shorter side of the die.

8. The method according to claim 7, wherein the cutting edge of the blade does not run parallel to that crystal axis of the die most in danger of fracture.

9. The method according to claim 7, wherein a length of the cutting edge is at least 10 times greater than a width of the cutting edge.

10. The method according to claim 8, wherein a length of the cutting edge is at least 10 times greater than a width of the cutting edge.
